(19) United States
(12) Patent Application Publication
(10) Pub. No.: US 2024/0404909 A1
(43) Pub. Date: Dec. 5, 2024

(54) PACKAGE STRUCTURE AND METHOD FOR FORMING THE SAME

(71) Applicant: Taiwan Semiconductor Manufacturing Company, Ltd., Hsinchu (TW)

(72) Inventors: Yu-Hung LIN, Hsinchu County (TW); Shih-Peng TAI, Hsinchu County (TW); Yu-Yi HUANG, Taipei City (TW); Yu-Hao KUO, Hsinchu County (TW)

(73) Assignee: Taiwan Semiconductor Manufacturing Company, Ltd, Hsinchu (TW)

(21) Appl. No.: 18/327,179

(22) Filed: Jun. 1, 2023

(51) Int. Cl. H01L 23/367; H01L 23/00; H01L 25/00; H01L 25/065; H01L 25/18; H10B 80/00

(52) U.S. Cl. CPC H01L 23/367; H01L 24/05; H01L 24/08; H01L 24/13; H01L 24/32; H01L 24/80; H01L 25/0657; H01L 25/18; H01L 25/50; H10B 80/00; H01L 23/49827; H01L 2224/05573; H01L 2224/05624; H01L 2224/05639; H01L 2224/05644; H01L 2224/05647; H01L 2224/05655; H01L 2224/05657; H01L 2224/05684; H01L 2224/08145; H01L 2224/08221; H01L 2224/13025; H01L 2224/13147; H01L 2224/32221; H01L 2224/80357; H01L 2224/80379; H01L 2225/06541; H01L 2225/06589; H01L 2924/05442; H01L 2924/059

(57) ABSTRACT

A method for forming a package structure is provided, wherein the method includes forming an interconnect structure in a substrate. The method also includes bonding a chip over the substrate and electrically connected to the interconnect structure. The method includes bonding a plurality of dies over the substrate and adjacent to the chip. The method also includes supplying a molding material to the gap between the chip and the dies, after which the method includes thinning down the substrate.

### BACKGROUND

The semiconductor industry continues to improve the integration density of various electronic components (e.g., transistors, diodes, resistors, capacitors, etc.) by continual reductions in minimum feature size, which allow more components to be integrated into a given area. The individual dies are typically packaged separately. A package not only provides protection for semiconductor devices from environmental contaminants, but also provides a connection interface for the semiconductor devices packaged therein.

Three dimensional integrated circuits (3DICs) are a recent development in semiconductor packaging in which multiple semiconductor dies are stacked upon one another, such as package-on-package (PoP) and system-in-package (SiP) packaging techniques. Some 3DICs are prepared by placing dies over dies on a semiconductor wafer level. 3DICs provide improved integration density and other advantages, such as faster speeds and higher bandwidth, because of the decreased length of interconnects between the stacked dies, for example. However, there are many challenges related to 3DICs.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIGS. 1A-1H are cross-sectional views illustrating various stages of forming a package structure in accordance with some embodiments of the present disclosure.

FIG. 2 is a cross-sectional view illustrating the package structure in accordance with some embodiments of the present disclosure.

FIG. 3 is a cross-sectional view illustrating the package structure in accordance with some embodiments of the present disclosure.

FIG. 4 is a top view illustrating the package structure in accordance with some embodiments of the present disclosure.

FIG. 5 is a top view illustrating the package structure in accordance with some embodiments of the present disclosure.

FIG. 6 is a cross-sectional view illustrating a package device in accordance with some embodiments of the present disclosure.

FIG. 7 is a cross-sectional view illustrating a package device in accordance with some embodiments of the present disclosure.

FIG. 8 is a cross-sectional view illustrating a package device in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments of package structures and method for forming the same are provided. The method for forming package structures includes thinning down the substrate after supplying the molding material to the gap between the chip and the dies. Accordingly, no carrier is required for forming the package structure, and therefore the process cost and time may be saved. The yield of the package structure may be increased since the formation process of package structure is simplified. In addition, the package structure includes multiple thermal-dissipation dies to provide uniform or local enhanced thermal dissipation for the package structure.

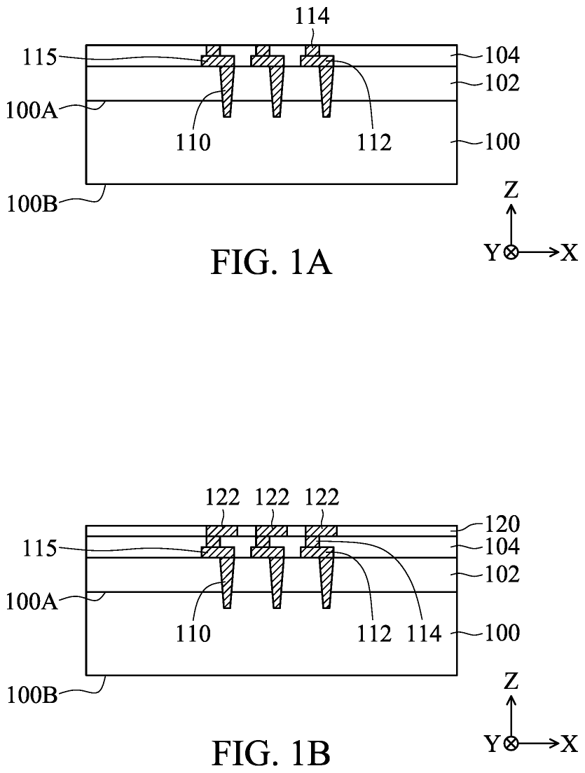

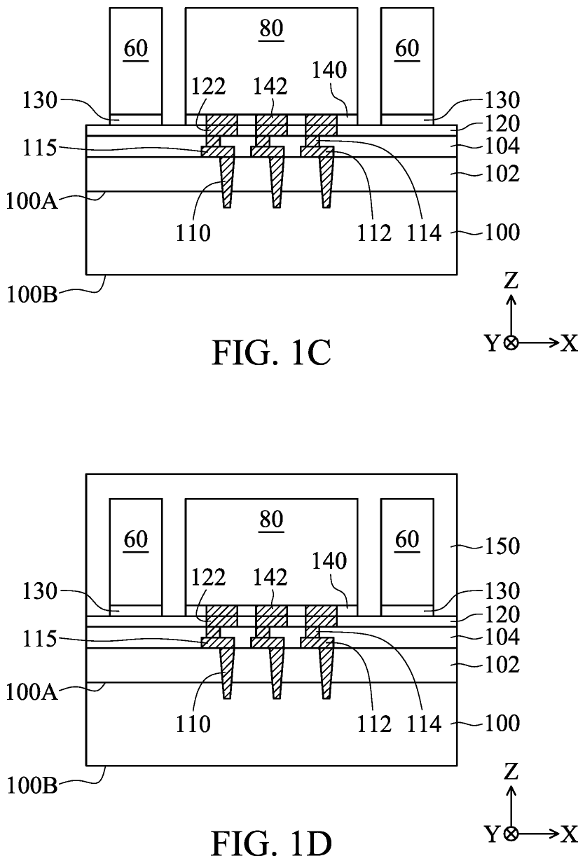

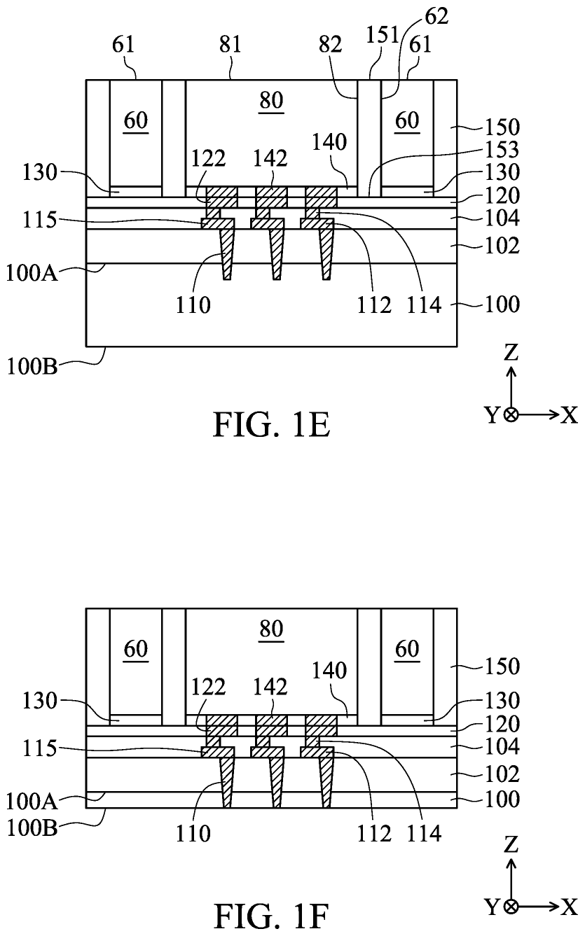

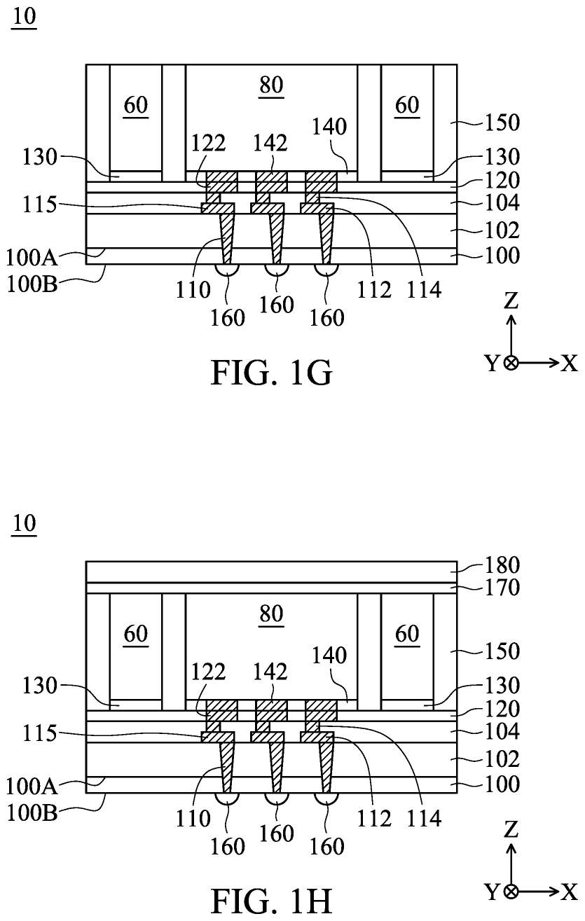

FIGS. 1A-1H are cross-sectional views illustrating various stages of forming a package structure 10 in accordance with some embodiments of the present disclosure. For example, a substrate 100 includes a semiconductor substrate, including such as silicon, doped or undoped, or an active layer of a semiconductor-on-insulator (SOI) substrate. In some embodiments, the substrate 100 includes other semiconductor materials, such as germanium; a compound semiconductor including silicon carbide, gallium arsenic, gallium phosphide, indium phosphide, indium arsenide, and indium antimonide; an alloy semiconductor including SiGe, GaAsP, AlInAs, AlGaAs, GaInAs, GaInP, and GaInAsP; or a combination thereof. Other substrates, such as multi-layered or gradient substrates, may also be used. In some embodiments, the substrate 100 has a first surface 100A, sometimes called a front side, and a second surface 100B, sometimes called a back side. In some embodiments, the first surface 100A is opposite the second surface 100B. The first surface 100A is connected to the second surface 100B via a sidewall of the substrate 100. In some embodiments, the first surface 100A is parallel to the second surface 100B.

In some embodiments, an interconnect structure 115 is formed in the substrate 100. In some embodiments, the interconnect structure 115 includes a plurality of through-silicon via (TSV) structures 110, a plurality of metallization patterns 112, and a plurality of conductive features 114. In some embodiments, the TSV structures 110 are formed in the substrate 100 and a dielectric layer 102 formed on the substrate 100. However, the present disclosure is not limited thereto. In some other embodiments, the dielectric layer 102 may be omitted, and the TSV structures 110 are completely located in the substrate 100.

In some embodiments, the dielectric layer 102 includes one or more sub-dielectric layers formed of materials such as silicon dioxide (SiO₂), Phospho-Silicate Glass (PSG), Boro-Silicate Glass (BSG), Boron-Doped Phospho-Silicate Glass (BPSG), undoped Silicate Glass (USG), or the like. In some embodiments, the dielectric layer 102 is formed, for example, by spin coating, lamination, chemical vapor deposition (CVD), or the like.

In some embodiments, the formation of the TSV structures 110 includes forming a plurality of trenches on the first surface 100A of the substrate 100. In some embodiments, the trenches extend into the substrate 100 and penetrate the dielectric layer 102 (if present) to electrically and physically couple the overlying metallization patterns 112. In some embodiments, the TSV structures 110 have a tapered profile in the cross-sectional view. For example, the width of the TSV structures 110 gradually decreases from the first surface 100A to the second surface 100B. However, the present disclosure is not limited thereto. In some other embodiments, the TSV structures 110 may have a rectangular profile in the cross-sectional view. In some embodiments, the TSV structures 110 are formed of tungsten (W), cobalt (Co), nickel (Ni), copper (Cu), silver (Ag), gold (Au), aluminum (Al), any other suitable conductive material, or a combination thereof. However, the present disclosure is not limited thereto.

The metallization patterns 112 and the conductive features 114 are surrounded by a dielectric layer 104 for proper insulation, reducing the probability of forming short-circuit. In some embodiments, the dielectric layer 104 includes one or more sub-dielectric layers formed of materials such as silicon dioxide (SiO₂), Phospho-Silicate Glass (PSG), Boro-Silicate Glass (BSG), Boron-Doped Phospho-Silicate Glass (BPSG), undoped Silicate Glass (USG), or the like. In some embodiments, the dielectric layer 104 is formed, for example, by spin coating, lamination, chemical vapor deposition (CVD), or the like. In some embodiments, the dielectric layer 104 is formed by using material or method that is the same as that of the dielectric layer 102. However, the present disclosure is not limited thereto. In some embodiments, the dielectric layer 104 is formed by using material or method that is different from that of the dielectric layer 102.

In some embodiments, one or more devices (not individually shown) are in the formed in first substrate 100 or overlaying dielectric layers 102, 104, and electrically connected to the TSV structures 110, the metallization patterns 112, and/or the conductive features 114. In some embodiments, the devices are active devices (e.g., transistors, diodes, etc.), capacitors, resistors, etc. For example, the devices are metal-oxide-semiconductor field-effect transistor (MOSFET), in accordance with some embodiments of the present disclosure.

In some embodiments, the metallization patterns 112 include metal lines and the conductive features 114 include vias formed in the dielectric layer 104. For example, the metallization patterns 112 and/or the conductive features 114 include conductive material such as tungsten (W), cobalt (Co), nickel (Ni), copper (Cu), silver (Ag), gold (Au), aluminum (Al), any other suitable conductive material, or a combination thereof. In some embodiments, the TSV structures 110, the metallization patterns 112, and/or the conductive features 114 are formed of the same material. In some other embodiments, the TSV structures 110, the metallization patterns 112, and/or the conductive features 114 are formed of different materials.

Accordingly, the TSV structures 110 is electrically connected to the metallization patterns 112 and the conductive features 114 for forming a conductive path connected to external environment (e.g. another semiconductor die or external devices). For example, when the devices in the substrate 100 are transistors, the TSV structures 110 may couple the gates or source/drain regions of the transistors. Source/drain regions may refer to a source or a drain, individually or collectively dependent upon the context.

As shown in FIG. 1B, a bonding film 120 is formed over the substrate 100 for the bonding process. For example, the material of the bonding film 120 includes SiON, SiO₂, any other suitable material, or a combination thereof. In some embodiments, a plurality of bonding pads 122 are formed in the bonding film 120. For example, the bonding pads 122 include conductive material such as tungsten (W), cobalt (Co), nickel (Ni), copper (Cu), silver (Ag), gold (Au), aluminum (Al), any other suitable conductive material, or a combination thereof. In some embodiments, the bonding pads 122 are formed corresponding to a chip 80 (for example, shown in FIG. 1C) to be bonded. However, the present disclosure is not limited thereto. In some embodiments, the bonding pads 122 are distributed more densely in the first region which overlaps (i.e. it is directly below) the chip 80 than in the second region which overlaps the dies 60.

As shown in FIG. 1C, a chip 80 is bonded over the first surface 100A of the substrate 100. For example, the chip 80 may be a device die, a package with a device die(s) packaged therein, a System-on-Chip (SoC) die including a plurality of device dies packaged as a system, or the like. The chip 80 may be or may comprise logic dies, memory dies, input-output dies, Integrated Passive Devices (IPDs), or the like, or combinations thereof. For example, the logic device dies in the chip 80 may be Central Processing Unit (CPU) dies, Graphic Processing Unit (GPU) dies, mobile application dies, Micro Control Unit (MCU) dies, BaseBand (BB) dies, Application processor (AP) dies, or the like. The memory dies in the chip 80 may include Static Random Access Memory (SRAM) dies, Dynamic Random Access Memory (DRAM) dies, or the like. The chip 80 may include semiconductor substrates and interconnect structures, which are not individually shown in the present embodiment.

In addition, another bonding film 140 is formed on the chip 80 for the bonding process. For example, the material of the bonding film 140 includes SiON, SiO₂, any other suitable material, or a combination thereof. In some embodiments, the material of the bonding film 140 is the same as the material of the bonding film 120. Although two bonding films (e.g. the bonding film 120 and the bonding film 140) are shown in the present disclosure, it should be appreciated that one or multiple (more than two) bonding films are also adopted in the present disclosure.

In some embodiments, a plurality of bonding pads 142 are formed in the bonding film 140. For example, the bonding pads 142 include conductive material such as tungsten (W), cobalt (Co), nickel (Ni), copper (Cu), silver (Ag), gold (Au), aluminum (Al), any other suitable conductive material, or a combination thereof. In some embodiments, the bonding pads 142 are each aligned with the bonding pads 122 over the first surface 100A of the substrate 100 to form electrical connection between the chip 80 and the interconnect structure 115.

In some embodiment, a plurality of dies 60 are also bonded over the first surface 100A of the substrate 100. For example, the dies 60 are formed based on semiconductor material (for example, silicon or any other suitable semiconductor material). Accordingly, the dies 60 may sometimes be referred to as “semiconductor dies 60.” In some embodiment, the dies 60 are bonded adjacent to and electrically isolated from the chip 80. These dies 60 are configured to help to dissipate the heat generated during the operation of the chip 80. Therefore, the dies 60 may also be referred to as “thermal-dissipation dies 60.”

In addition, another bonding film 130 is formed on the dies 60 for the bonding process. For example, the material of the bonding film 130 includes SiON, SiO₂, any other suitable material, or a combination thereof. In some embodiments, the material of the bonding film 130 is the same as the material of the bonding film 120. Although two bonding films (e.g. the bonding film 120 and the bonding film 130) are shown in the present disclosure, it should be appreciated that one or multiple (more than two) bonding films are also adopted in the present disclosure. In some embodiments, no bonding pad is formed in the bonding film 130 and a corresponding (i.e. overlapped) region of the bonding film 120 for bonding the dies 60. However, the present disclosure is not limited thereto.

Then, as shown in FIG. 1D, a molding material 150 is supplied over the first surface 100A of the substrate 100 and covers the chip 80 and the dies 60. After formation, the molding material 150 encapsulates the chip 80 and the dies 60 over the first surface 100A of the substrate 100. In some embodiments, the molding material 150 may include epoxy molding compound (EMC). For example, the molding material 150 includes polymethyl methacrylate (PMMA), acrylonitrile butadiene styrene (ABS), polyamide (PA), polycarbonate (PC), polyethylene (PE), polyoxymethylene (POM), polypropylene (PP), polystyrene (PS), thermoplastic elastomer (TPE), thermoplastic polyurethane (TPU), etc.), epoxy, or the like. In some embodiments, the molding material 150 is supplied by compression molding, transfer molding, or the like. In some embodiments, the molding material 150 is supplied in liquid or semi-liquid form and then subsequently cured, which increases the mobility of the molding material 150 and therefore being able to fill in the gap between the chip 80 and the dies 60 with relatively high aspect ratio.

Next, as shown in FIG. 1E, a planarization process (such as, chemical mechanical polish (CMP), molding compound grinding (MCG) or any other suitable planarization process) may be performed to remove and planarize the upper surface of the molding material 150. As a result, the top surface 151 of the molding material 150, the top surfaces 61 of the dies 60 and the top surface 81 of the chip 80 are substantially coplanar (within process variation). In some embodiments, the molding material 150 fills in the gap between the chip 80 and the dies 60 with a relatively high aspect ratio, the width of the gap may be defined as the width between the sidewall 82 of the chip and the sidewall 62 of the adjacent die 60, and the height of the gap may be defined as the height between the top surface 151 (which may be coplanar with the top surface 81 of the chip 80) and the bottom surface 153 (which may be coplanar with the top surface of the bonding film 120) of the molding material 150. In some embodiments, the molding material 150 fills in the gap higher than about 20 μm. As a result, higher chip 80 and dies 60 may be bonded over the first surface 100A of the substrate 100, and the height of the chip 80 and the dies 60 will not be limited by the formation of the molding material 150.

As shown in FIG. 1F, the substrate 100 is thinned down to expose the TSV structures 110 on the second surface 100B of the substrate 100. That is, after the thinned down process, the bottom surface of the TSV structures 110 may be substantially coplanar with the second surface 100B of the substrate 100. In some embodiment, the substrate 100 is trimmed in a direction perpendicular to the first surface 100A and the second surface of the substrate 100. In some embodiments, the substrate 100 is thinned down using a polishing process, a grinding process, any other suitable process, or a combination thereof. To be more specific, the polishing process and/or the grinding process may be performed on the second surface 100B of the substrate. In the present embodiment, the second surface 100B of the substrate 100 is thinned down while the chip 80 and the semiconductor dies 60 are located over the first surface 100A of the substrate 100. Accordingly, no carrier is required for forming the package structure 10, and therefore the process cost and time may be saved. Also, the yield of the package structure 10 may be increased since the formation process of package structure 10 is simplified (in particular, the bonding and removal of the carrier are omitted, and the substrate 100 is processed without being flipped).

As shown in FIG. 1G, a plurality of bump structures 160 are formed on the exposed TSV structures 110. That is, the bump structures 160 are formed on the second surface 100B of the substrate 100 and cover the exposed surfaces of the TSV structures 110. In some embodiments, a contact area between the metallization patterns 112 and the TSV structures 110 is greater than a contact area between the TSV structures 110 and the bump structures 160. That is, a surface area of the TSV structures 110 on the first surface 100A is greater than a surface area of the TSV structures 110 on the second surface 100B. In some embodiments, the bump structures 160 may include controlled collapse chip connection (C4) bumps, solder bumps, copper bumps, micro bumps, electroless nickel-electroless palladium-immersion gold technique (ENEPIG) formed bumps, ball grid array (BGA) bumps, copper pillars, or the like.

As shown in FIG. 1H, a thermal interface material (TIM) 170 is optionally disposed on the chip 80 and the dies to enhance the thermal-dissipation of the package structure 10. To be more specific, the thermal interface material 170 fully covers the top surfaces of the chip 80 and the dies 60 to dissipate the generated heat. In some embodiments, the thermal interface material 170 also covers the top surface of the molding material 150. However, the present disclosure is not limited thereto. In some embodiments, the thermal interface material 170 may selectively exposes the molding material 150. As a result, the process cost may be saved.

In addition, a heat sink 180 may be mounted over the chip 80 and the dies 60. For example, the heat sink 180 may be placed, attached via connectors (e.g., screws, pins, and/or other similar hardware), and/or adhered (e.g., via an epoxy adhesive and/or another type of adhesive) to the thermal interface material 170 (if present). In some embodiments, the heat sink 180 may be mounted directly over the chip 80 and the dies 60. For example, the heat sink 180 may include a fan and/or another similar type of hardware that causes heat generated during use of the chip 80 to an environment outside the chip 80. However, the present disclosure is not limited thereto.

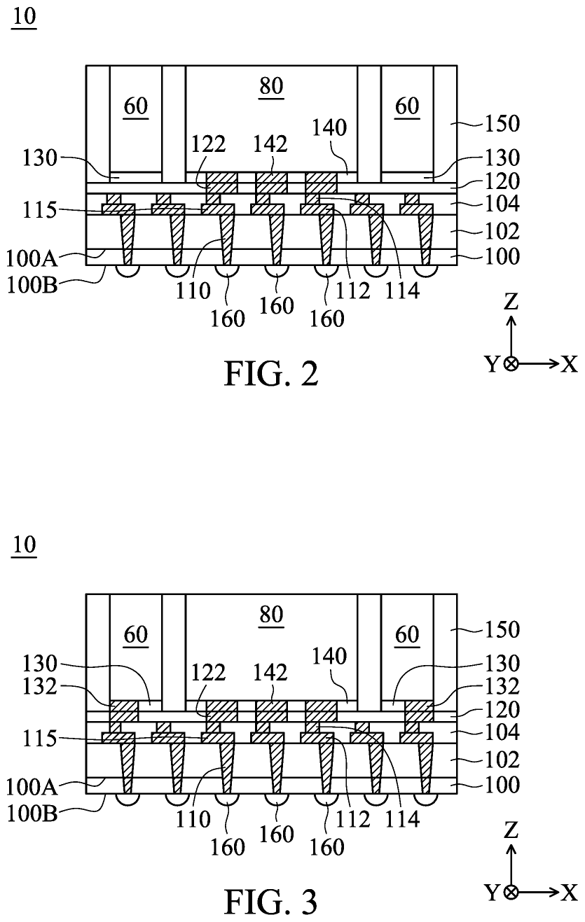

FIG. 2 is a cross-sectional view illustrating the package structure 10 in accordance with some embodiments of the present disclosure. It should be noted that the package structure 10 in the present embodiment may include elements that are the same or similar to the package structure 10 shown in FIG. 1. These elements will be denoted by the same or similar numerals and will not be discussed in detail in the following paragraphs. As shown in FIG. 2, the package structure 10 includes a substrate 100, an interconnect structure 115, a chip 80 and a plurality of dies 60. The chip 80 and the dies 60 are bonded over the first surface 100A of the substrate 100 via multiple bonding films 120, 130, and 140. In the present embodiment, the TSV structures 110 are uniformly distributed across the substrate 100. That is, the dies overlap some of the TSV structures 110 in a normal direction perpendicular to the first surface 100A. Accordingly, the interconnect structure 115 may be routed more flexible, and the underlying bump structures 160 may also be formed across the whole substrate 100. As a result, various arrangement of the chip 80 and the dies 60 may be adopted to the substrate 100. In some embodiments, the TSV structures 110 are spaced apart from each other at a constant interval. However, the present disclosure is not limited thereto.

FIG. 3 is a cross-sectional view illustrating the package structure 10 in accordance with some embodiments of the present disclosure. It should be noted that the package structure 10 in the present embodiment may include elements that are the same or similar to the package structure 10 shown in FIG. 1. These elements will be denoted by the same or similar numerals and will not be discussed in detail in the following paragraphs. As shown in FIG. 3, the package structure 10 includes a substrate 100, an interconnect structure 115, a chip 80 and a plurality of dies 60. The chip 80 and the dies 60 are bonded over the first surface 100A of the substrate 100 via multiple bonding films 120, 130, and 140. In the present embodiment, the TSV structures 110 are formed across the substrate 100, and at least one bonding pad 132 is formed in the bonding film 130 for bonding the dies 60. The bonding pad 132 is aligned with the underlying bonding pad 122. For example, a sidewall of the bonding pad 132 is substantially coplanar with a corresponding sidewall of the bonding pad 122 in a vertical direction (which is, for example, parallel to the Z axis). In some embodiments, the thermal-dissipation dies 60 each include metallic patterns (not individually shown) that is physically connected to the bonding pad 132 and electrically isolated from the chip 80. Accordingly, the thermal-dissipation effect may be further improved.

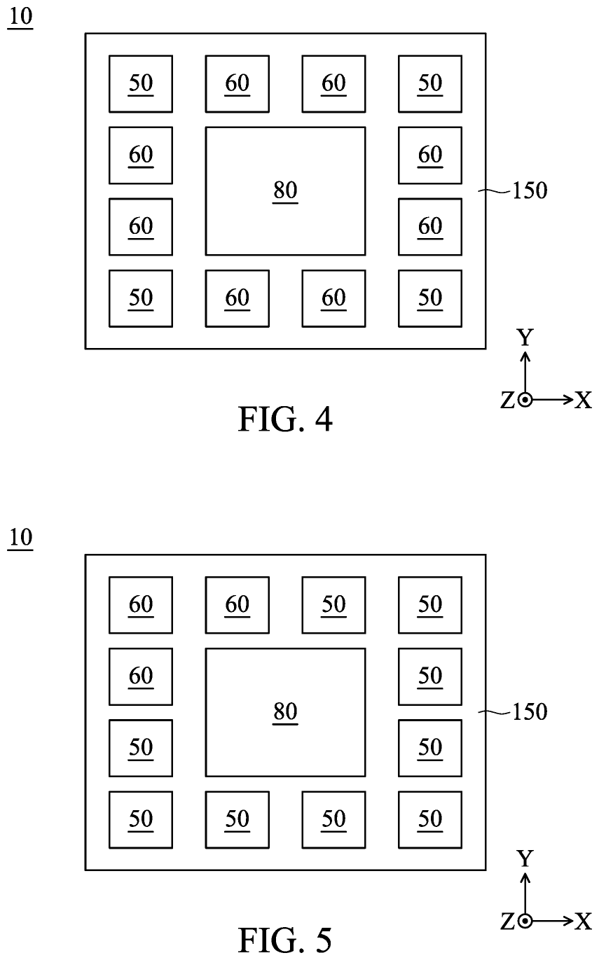

FIG. 4 is a top view illustrating the package structure 10 in accordance with some embodiments of the present disclosure. As shown in FIG. 4, a plurality of semiconductor dies 50 and 60 are bonded over the first surface 100A of the substrate 100 and around the chip 80. In some embodiments, the semiconductor dies 50 may include active and/or passive devices and be electrically connected to the chip 80 to improve the performance of the package structure 10. Examples of semiconductor dies 50 include a wide variety of devices such as transistors, capacitors, resistors, combinations of these, and the like, and they may be used to generate the structural and functional requirements of the design for the package structure 10. In some embodiments, the semiconductor dies 50 are formed using any suitable method.

The semiconductor dies around the chip 80 also includes thermal-dissipation dies 60 that is electrically isolated from the chip 80. In some embodiments, the thermal-dissipation dies 60 are bonded on each side of the chip 80. In some embodiments, the thermal-dissipation dies 60 are symmetrically arranged around the chip 80 so as to provide uniform thermal dissipation for the package structure 10. It should be noted that the arrangement of the semiconductor dies 50 and 60 shown in this embodiment merely serves as an example, and those skilled in the art would adjust the positions of the semiconductor dies 50 and 60 as required according to the present disclosure.

FIG. 5 is a top view illustrating the package structure 10 in accordance with some embodiments of the present disclosure. It should be noted that the package structure 10 in the present embodiment may include elements that are the same or similar to the package structure 10 shown in FIG. 4. These elements will be denoted by the same or similar numerals and will not be discussed in detail in the following paragraphs. As shown in FIG. 5, a plurality of semiconductor dies 50 and a plurality of thermal-dissipation dies 60 are bonded over the first surface 100A of the substrate 100 and located around the chip 80. In some embodiments, the thermal-dissipation dies 60 are bonded at one corner of the chip 80 so as to strengthen local thermal dissipation for the package structure 10. Similarly, it should be noted that the arrangement of the semiconductor dies 50 and 60 shown in this embodiment merely serves as an example, and those skilled in the art would adjust the positions of the semiconductor dies 50 and 60 as required according to the present disclosure. All the possible arrangement of the semiconductor dies 50 and 60 are contemplated within the scope of the present disclosure.

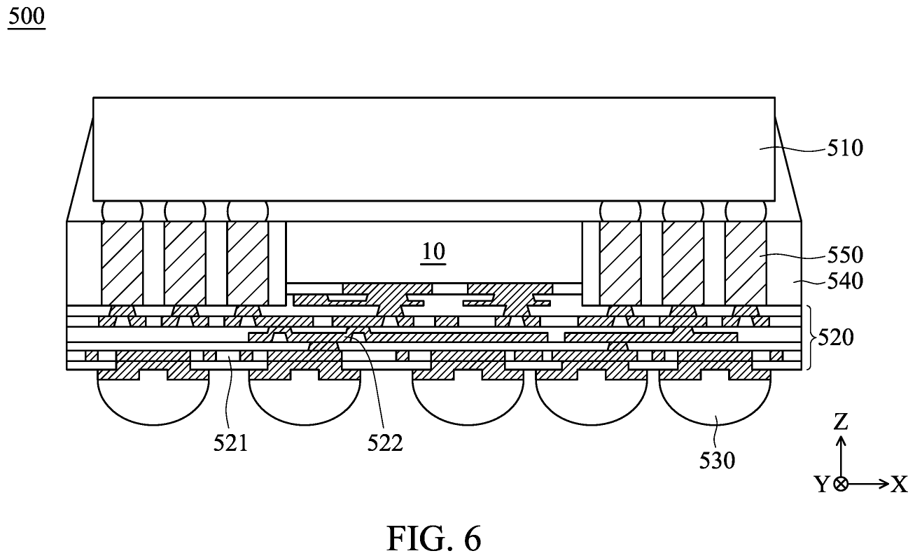

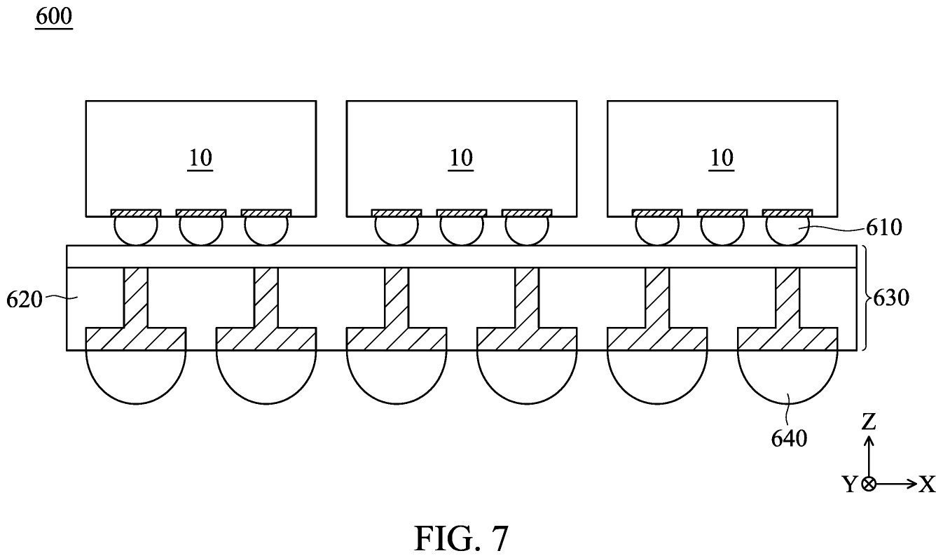

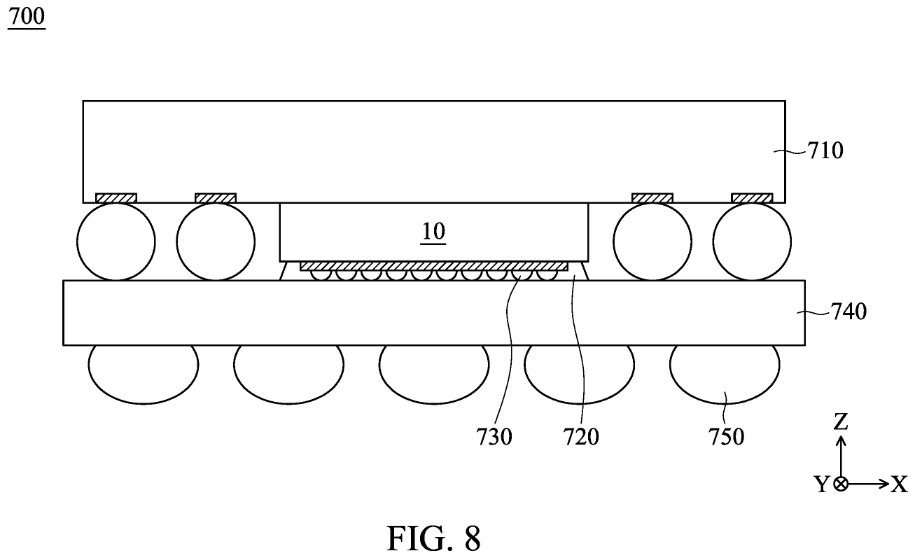

FIGS. 6-8 are cross-sectionals view illustrating package devices 500, 600, and 700 including the package structure 10, in accordance with some embodiments. Additional features may be added to the package devices 500, 600, and 700, and some of the features described below can be replaced, modified, or eliminated in other embodiments of the package devices 500, 600, and 700. The package structure 10 is simplified in FIGS. 6-8 for the sake of clarity.

In addition to the package structure 10, the package device 500 includes a semiconductor die 510, a fan-out redistribution structure 520, a plurality of conductive connectors 530, an underfill layer 540, and a plurality through integrated fan-out (InFO) vias (TIV) 550. The term “fan-out” means that the I/O pads on the package structure 10 can be redistributed to a greater area than the package structure 10 itself, and thus the number of I/O pads packed on the surfaces of the package structure 10 can be increased.

The semiconductor die 510 may be a logic die, a memory die, a passive device die, an analog die, a MEMS die, a radio frequency RF die, or a combination thereof. For example, a logic die may be a central processing unit die, a SoC die, a SOIC die, a microcontroller die, or the like. A memory die may be a DRAM die, a SRAM die, a HBM die, a NAND die, or the like.

The fan-out redistribution layer 520 may include a plurality of dielectric layers 521 and a plurality of conductive layers 522. The conductive connectors 530 are formed over the conductive layers 522 that are exposed from the dielectric layers 521. In some embodiments, the conductive connectors 530 are controlled collapse chip connection (C4) bumps, solder bumps, copper bumps, micro bumps, electroless nickel-electroless palladium-immersion gold technique (ENEPIG) formed bumps, ball grid array (BGA) bumps, copper pillars, or the like. The underfill layer 540 is formed to surround the package structure 10. In some embodiments, the underfill layer 540 is made of or includes a polymer material. The underfill layer 540 may include an epoxy-based resin. In some embodiments, the underfill layer 540 includes fillers dispersed in the epoxy-based resin. In some embodiments, the formation of the underfill layer 540 involves an injecting process, a spin-on process, a dispensing process, a film lamination process, an application process, one or more other applicable processes, or a combination thereof. In some embodiments, a thermal curing process is used during the formation of the underfill layer 540. The TIVs 550 penetrate the underfill layer 540 to provide electrical connection.

In addition to the package structure 10, the package device 600 includes a plurality of contact bumps 610, an interposer 620, a redistribution structure 630, and a plurality of conductive connectors 640.

The contact bumps 610 are formed under the package structure 10 to provide electrical connection. The interposer 620 may be fabricated from a silicon material, an organic (laminate) material, a polymer-based material, or the like. The interposer 620 may be attached to a carrier such as a printed circuit board (PCB). The redistribution structure 630 may include metal lines and vias to provide electrical connection to route power, ground, and signals from the top surface of the interposer 620 to the bottom surface of the interposer 620. In some embodiments, the conductive connectors 640 are C4 bumps, solder bumps, copper bumps, micro bumps, ENEPIG formed bumps, BGA bumps, copper pillars, or the like.

In addition to the package structure 10, the package device 700 includes a semiconductor die 710, an underfill layer 720, a plurality of contact pads 730, a bottom substrate 740, and a plurality of conductive connectors 750.

The semiconductor die 710 may be a logic die, a memory die, a passive device die, an analog die, a MEMS die, a radio frequency RF die, or a combination thereof. Examples of a logic die include a central processing unit die, a SoC die, a SOIC die, a microcontroller die, and the like. A memory die may be a DRAM die, a SRAM die, a HBM die, a NAND die, or the like. The contact pads 730 are formed within the underfill layer 720 to provide an electrical connection. In some embodiments, the conductive connectors 750 are C4 bumps, solder bumps, copper bumps, micro bumps, ENEPIG formed bumps, BGA bumps, copper pillars, or the like. In some embodiments, the package structure 10 may be connected to the bottom substrate 740 by flip-chip bonding technology.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes, the use of probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

As described above, the present disclosure is directed to package structures and methods for forming the same. The method for forming package structures includes thinning down the substrate after supplying the molding material to the gap between the chip and the dies. Accordingly, no carrier is required for forming the package structure, and therefore the process cost and time may be saved. The yield of the package structure may be increased since the formation process of package structure is simplified. In particular, the bonding and removal of the carrier are omitted, and the substrate 100 is processed without being flipped. In addition, the package structure includes multiple thermal-dissipation dies to provide uniform or local enhanced thermal dissipation for the package structure, depending the positions of the thermal-dissipation dies around the chip.

In accordance with some embodiments, a method for forming a package structure includes forming an interconnect structure in a substrate. The method also includes bonding a chip over the substrate and electrically connected to the interconnect structure. The method includes bonding a plurality of dies over the substrate and adjacent to the chip. The method further includes supplying a molding material to a gap between the chip and the dies. In addition, the method includes after supplying the molding material to the gap between the chip and the dies, thinning down the substrate.

In accordance with some embodiments, a method for forming a package structure includes forming a plurality of through-substrate via (TSV) structures in a substrate. The method includes bonding a chip over a first surface of the substrate and electrically connected to a first plurality of the TSV structures. The method includes bonding a thermal-dissipation die over the first surface of the substrate and adjacent to the chip. The thermal-dissipation die overlaps a second plurality of the TSV structures in a normal direction perpendicular to the first surface. The method includes supplying a molding material to a gap between the chip and the thermal-dissipation die. The method also includes thinning down the substrate from a second surface opposite the first surface.

In accordance with some embodiments, a package structure includes a substrate that has a first surface and a second surface. The second surface is opposite the first surface. The package structure includes a plurality of through-substrate via (TSV) structures formed in a substrate. The width of the TSV structures gradually decreases from the first surface to the second surface. The package structure includes a chip bonded to the first surface of the substrate. The package structure also includes a plurality of dies bonded to the first surface of the substrate and located adjacent to the chip. The package structure further includes a molding material formed between the chip and the dies. In addition, the package structure includes a plurality of bump structures connected to the TSV structures on the second surface.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a package structure, comprising:
forming an interconnect structure in a substrate;
bonding a chip over the substrate and electrically connected to the interconnect structure;
bonding a plurality of dies over the substrate and adjacent to the chip;
supplying a molding material to a gap between the chip and the dies; and
after supplying the molding material to the gap between the chip and the dies, thinning down the substrate.

2. The method as claimed in claim 1, further comprising:
forming a plurality of bump structures on the exposed interconnect structure,
wherein a bottom surface of the interconnect structure is exposed after thinning down the substrate, and the bump structures are connected to the bottom surface of the interconnect structure.

3. The method as claimed in claim 1, further comprising:
forming a bonding film over the substrate; and
forming a plurality of bonding pads in the bonding film, wherein the bonding pads are distributed more densely in a first region overlapping the chip than a second region overlapping the dies.

4. The method as claimed in claim 3, wherein forming the interconnect structure in the substrate comprises forming a plurality of through-substrate via (TSV) structures from a first surface to a second surface, a width of the TSV structures on the first surface is greater than a width of the TSV structures on the second surface, and the bonding pads are formed over the first surface.

5. The method as claimed in claim 1, wherein the dies comprise a plurality of thermal-dissipation dies that are electrically isolated from the chip.

6. The method as claimed in claim 5, wherein the thermal-dissipation dies are symmetrically arranged around the chip.

7. The method as claimed in claim 1, further comprising:
forming a plurality of trenches on a first surface of a substrate;
filling a conductive material to form a plurality of through-substrate via (TSV) structures in the substrate;
forming a dielectric layer over the first surface of the substrate;
forming a plurality of metallization patterns in the dielectric layer, wherein the metallization patterns are electrically connected to the TSV structures.

8. A method for forming a package structure, comprising:
forming a plurality of through-substrate via (TSV) structures in a substrate;
bonding a chip over a first surface of the substrate and electrically connected to a first plurality of the TSV structures;
bonding a thermal-dissipation die over the first surface of the substrate and adjacent to the chip, wherein the thermal-dissipation die overlaps a second plurality of the TSV structures in a normal direction perpendicular to the first surface;
supplying a molding material to a gap between the chip and the thermal-dissipation die; and
thinning down the substrate from a second surface opposite the first surface.

9. The method as claimed in claim 8, further comprising:
forming a plurality of bonding pads in a bonding film over the first surface, wherein the bonding pads are electrically connected to the first plurality of the TSV structures.

10. The method as claimed in claim 8, wherein the TSV structures are uniformly distributed across the substrate.

11. The method as claimed in claim 8, wherein the thermal-dissipation die is electrically isolated from the chip.

12. The method as claimed in claim 11, wherein bonding the thermal-dissipation die further comprises aligning a bonding pad of the thermal-dissipation die with a bonding pad over the substrate.

13. The method as claimed in claim 8, wherein bonding the chip and the thermal-dissipation die comprises leveling a top surface of the chip with a top surface of the thermal-dissipation die.

14. The method as claimed in claim 8, wherein the substrate is thinned down from the second surface of the substrate to expose the TSV structures while the chip and the thermal-dissipation die are located over the first surface of the substrate.

15. The method as claimed in claim 14, further comprising:
forming a plurality of bump structures on the exposed TSV structures, wherein a surface area of the TSV structures on the first surface is greater than a surface area of the TSV structures on the second surface.

16. A package structure, comprising:
a substrate having a first surface and a second surface opposite the first surface;
a plurality of through-substrate via (TSV) structures in the substrate, wherein a width of the TSV structures gradually decreases from the first surface to the second surface;
a chip bonded to the first surface of the substrate;
a plurality of dies bonded to the first surface of the substrate and located adjacent to the chip;
a molding material between the chip and the dies; and
a plurality of bump structures connected to the TSV structures on the second surface.

17. The package structure as claimed in claim 16, further comprising a bonding film over the first surface, wherein a plurality of bonding pads are located in the bonding film and electrically connected to the TSV structures.

18. The package structure as claimed in claim 17, wherein the TSV structures are disposed across the substrate, and a portion of the TSV structures is misaligned with the bonding pads.

19. The package structure as claimed in claim 16, further comprising:
a thermal interface material formed over the chip and the dies; and
a heat sink formed over the thermal interface material.

20. The package structure as claimed in claim 16, further comprising:
a plurality of thermal-dissipation dies bonded on each side of the chip and electrically isolated from the chip.
